(19) United States
(12) Patent Application Publication
(10) Pub. No.: US 2025/0351588 A1
(43) Pub. Date: Nov. 13, 2025

(54) Highly Sensitive and Efficient 1550 nm Photon Detector For Room Temperature Operation

(71) Applicants: Srinivasan Krishnamurthy, Cupertino, CA (US); Zhi Gang Yu, Spokane, WA (US); Shanhui Fan, Stanford, CA (US); Rituraj Rituraj, Patthar (IN)

(72) Inventors: Srinivasan Krishnamurthy, Cupertino, CA (US); Zhi Gang Yu, Spokane, WA (US); Shanhui Fan, Stanford, CA (US); Rituraj Rituraj, Patthar (IN)

(21) Appl. No.: 19/047,499

(22) Filed: Feb. 6, 2025

Related U.S. Application Data
(60) Provisional application No. 63/550,258, filed on Feb. 6, 2024.

(51) Int. Cl. H10F 30/223; H10F 30/21; H10F 30/225; H10F 77/124; H10F 77/169

(52) U.S. Cl. CPC H10F 30/223; H10F 30/289; H10F 77/1248; H10F 77/169; H10F 30/225

(57) ABSTRACT

Effective quantum communication is achieved by room temperature (RT) operating single photon sensor with high photo detection efficiency (PDE) at 1550 nm wavelength. The leading class of devices in this segment is avalanche photo detectors operating particularly in the Geiger mode. A device is provided which employs a two-dimensional (2D) semiconductor material on a co-optimized dielectric photonic crystal substrate to simultaneously decrease the dark current by orders of magnitude and increase the PDE. The device is predicted to achieve RT operation with a PDE >99%. Harnessing the high carrier mobility of 2D materials, the device has ˜ps jitter time and can be integrated into a large 2D array camera.

This application claims the benefit of U.S. Provisional Application 63/550,258 filed Feb. 6, 2024.

### BACKGROUND

Detecting a low photon flux is increasingly important to the emerging fields of single-photon imaging, intensity correlation imaging, optical communication and LIDAR in photon-starving environments. The technologically matured CMOS detectors are readily available in the form of a large array and operate at room temperature, but suffer from poor sensitivity (≥100,000 photons), low efficiency and high dark current, making them unsuitable for the aforementioned applications. On the other end of the spectrum, there are highly sensitive single-photon detectors (˜ 1 photon) which are expected to be a key enabler of all large and intermediate scale photonic quantum technologies including quantum computation, communication, and sensing. The present inventors have recognized it would be desirable to have a room-temperature, high efficiency, fast, large array of single photon detectors. Unfortunately, the three leading technologies—superconducting nanowire single-photon detectors (SNSPDs), transition-edge sensors (TESs), and single photon avalanche diodes (SPADs)—are lacking in multiple of these fronts. These issues are further exacerbated—for both CMOS cameras and single-photon detectors—at the operating photon wavelength of 1550 nm. To date almost all the 1550 nm single-photon or quantum imaging demonstrations have been carried out either by raster-scanning single APD/SPAD/SNSPDs or by using small arrays with extremely slow readout, poor SNR, low spatial resolution, and in limited application scenarios. Thus, the present inventors have recognized that there is a need to develop highly sensitive large-array cameras for detecting low fluxes of 1550 nm photons with high temporal resolution (high frame/readout rate) at room temperature.

For 1550 nm-detection, the state-of-the art SPAD is InGaAs grown on InP. However, the dark current density near breakdown is ˜ 2×10⁻⁵ A/cm² at RT². To get dark counts to 10⁴ per second, these SPADs must be cooled (˜230 K) to reduce the dark current density.

The present inventors have recognized that for RT operation, a dark current density of 2×10⁻⁷ A/cm² is desired. The dark current density can be lowered by reducing the absorber volume, but only at the cost of lowering the photo detection efficiency (PDE). Even with a few micron-thick absorber at 230K, the demonstrated PDE is only ˜0.3. On the other hand, a few monolayers (MLs) of 2D materials such as MoS₂ and WSe₂, have been used as a photo detector with a dark current of 10-12 A. However, the PDE in these 2D devices is ˜ 0.01.

### SUMMARY

A novel detector platform is provided utilizing the material advances in the 2D semiconductors as well as dielectric metasubstrates with tailored photonic properties. Furthermore, the detector has the potential of achieving single-photon detection with all the above desired qualities.

A design is provided for detecting low-photon flux and possibly to a single-photon level at room temperature is provided. The designed structure is comprised of a 2D semiconductor on a photonic crystal substrate for simultaneously achieving low dark current and high PDE. The design overcomes the inherent limiting tradeoff between photo detection efficiency and SNR in the state-of-the-art SPADs and can be readily extended to 2D materials that absorb light at other desired wavelengths. Theoretically, the proposed device can be both ultrasensitive and highly efficient at room temperature. The results presented here clearly establish the numerous advantages over the existing single photon detectors (SPDs).

Numerous other advantages and features of the present invention will become readily apparent from the following detailed description of the invention and the embodiments thereof, from the claims and from the accompanying drawings.

### BRIEF DESCRIPTION OF THE DRAWINGS

FIG. 1 is a perspective schematic view of the room-temperature high efficiency photon detector using 2D semiconductor on a suitably designed photonic crystal substrate;

FIG. 2 is a perspective schematic view of an optimized 1550 nm SPD device structure consisting of ML BAs sandwiched between h-BN on a specifically designed photonic crystal substrate.

FIG. 3A is an absorption spectrum at normal incidence (θ=0) for different numbers of h-BN layers used to sandwich BAs absorber b) At different incident angles, as a function of free space wavelength.

FIG. 3B is an absorption spectrum at different incident angles, as a function of free space wavelength.

FIG. 4A is a schematic sectional The PiN device with ML BAs on a designed PCS substrate,

FIG. 4B is a schematic calculated absorption profile,

FIG. 4C is a graph of the predicted I-V curves with (red) and without (blue) 0.1 mW/cm² of 1550 nm illumination; and

FIG. 4D is a graph of the resulting ratio of photo to dark current.

### DETAILED DESCRIPTION

While this invention can be realized in a variety of forms, there are shown in the drawings, and will be described herein in detail, a specific embodiment for a particular vacuum system and shutter application with the understanding that the present disclosure exemplifies the principles of the invention and is not intended to limit the invention to this specific form or application.

This application incorporates by reference U.S. Provisional Application 63/550,258 filed Feb. 6, 2024 lin its entirety.

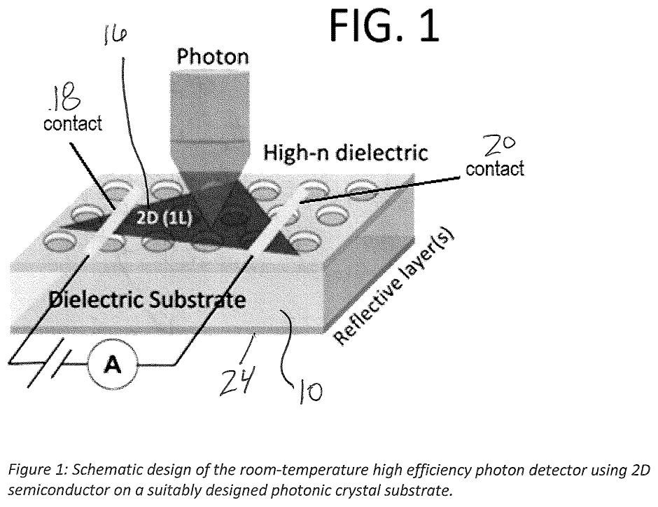

FIG. 1 shows a perspective schematic view of a room-temperature high efficiency photon detector using 2D semiconductor on a suitably designed photonic crystal substrate;

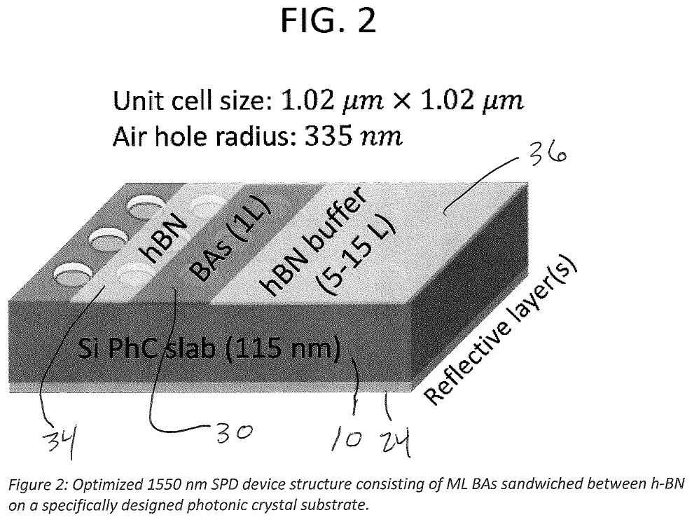

FIG. 2 shows an optimized 1550 nm SPD device structure consisting of ML BAs sandwiched between h-BN on a specifically designed photonic crystal substrate.

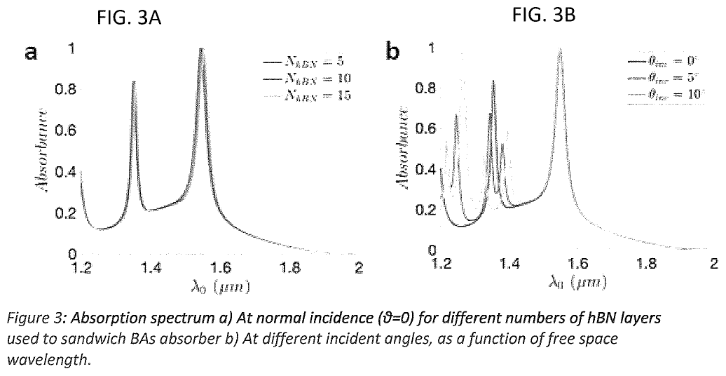

FIG. 3A-3B show an absorption spectrum a) At normal incidence (θ=0) for different numbers of h-BN layers used to sandwich BAs absorber b) At different incident angles, as a function of free space wavelength.

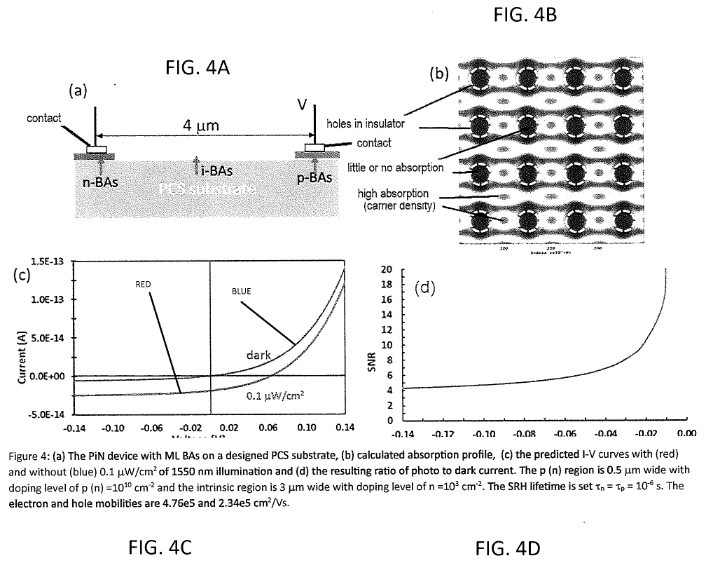

FIG. 4A-4D show (a) The PiN device with ML BAs on a designed PCS substrate, (b) calculated absorption profile, (c) the predicted I-V curves with (red) and without (blue) 0.1 mW/cm² of 1550 nm illumination and (d) the resulting ratio of photo to dark current. The p (n) region is 0.5 mm wide with doping level of p (n)=10¹⁰ cm⁻² and the intrinsic region is 3 mm wide with doping level of n=10³ cm⁻². The SRH lifetime is set tₙ=tₚ=10⁻⁶ s. The electron and hole mobilities are 4.76e5 and 2.34e5 cm²/Vs.

FIG. 1 shows a low-photon detector includes a 2D semiconductor on a photonic crystal substrate for simultaneously achieving low dark current and high PDE.

In one embodiment, a photoconductor design includes a substrate, photonic crystal slab (PCS) 10 made of transparent (to 1550 nm) material, and a layer of 2D material 16 with a band gap of ˜500 meV, as shown in FIG. 1. In this design, 2D materials such as BAs, BP, InSe, Zn₃P₂, NiP₂ or thin layer of 3D materials such as InGaAs, AlInAsSb or AlGaAsSb digital and random alloys with a band gap of 2 μm on the PCS substrate can be used to achieve the RT operating and ultra-sensitive SPADs. The PCS can be designed to increase the absorption of 1550 nm photons fully within a monolayer and the dark current is in pA. Further calculation of photo current-voltage (I-V) shows a SNR of >2 without carrier multiplication (avalanching) for incident light intensity of 100 nW/cm². Since the carrier path length between the contacts can be a few microns, the device can be designed to have avalanching as well to further increase the detectivity.

Contacts 18, 20 are provided. A reflective layer 24 can be provided beneath the substate 10.

### Design Principle and Device Performance:

The dark current in photo detectors arise from various recombinations such as Auger, radiative, and defect-mediated Shockley-Read-Hall mechanisms, and is proportional to the absorber volume. There is a constant effort to shrink the area by requiring smaller pitch and dense arrays. To realize a high PDE, the absorber thickness is usually three times the inverse of the absorption coefficient. For absorbers like InGaAs, the thickness needs to be ˜ 5 mm. A reduction in thickness will linearly decrease dark current, but, unfortunately, also lower the quantum efficiency. The thickness alone cannot be reduced to get the two orders of magnitude decrease in dark current desired for room temperature (RT) operation. On the other hand, 2D materials show considerable promise with high absorption, large mobility, and lack of surface states. For example, the photo detectors made of monolayer (ML) 2D materials show extremely low dark currents ˜pA with a PDE of about 1-3%. Further increase in absorption while maintaining low dark current requires a clever design.

A few years ago, a photonic crystal substrate (PCS) was designed to absorb nearly 100% of 1550 nm light within one monolayer (ML) of graphene placed on it and the design was later demonstrated to absorb ˜90%. In these works, the PCS (square lattice of air holes in silicon) was designed to support a leaky guided resonant mode at the desired frequency which couples to normally incident light from air. Thus, by coupling the incident light into a guided mode which travels parallel to the substrate, the effective path length of the light in the absorber is increased, resulting in high absorption. Achieving 100% absorption additionally can require critical coupling condition—a delicate balance between the absorption rate in the ML and the coupling rate of the incident light into the guided resonance (γ_{abs}=γ_{c})—to be fulfilled.

TABLE 1
DFT values calculated for bilayer h-

| Stacking | AB | AB′ |
|---|---|---|
| E_{g} [eV] | 0.6 | 0.3 |
| ΔE [meV] | 3.2 | 0 |
| dᵢₚ [Å] | 1.955 | 1.955 |
| dₒₚ [Å] | 3.573 | 3.516 |
| α₁₅₅₀[cm⁻¹] | 5.3 × 10⁴ | 4 × 10⁴ |
| n₁₅₅₀ | 3.8 | 3.8 |
| k₁₅₅₀ | 0.66 | 0.49 |

An approach of the present application is to exploit the low dark current in 2D material and design an appropriate PCS to redirect the normally incident light to travel parallel within the 2D layer. By doing this, we obtain a longer path length to achieve a PDE of ˜1 while keeping the dark current low (in pA) at RT. The graphene used in the previously published designs cannot be used for photo detection as it doesn't have a band gap, and the large absorption arises from free carriers and not across a band gap. For 1550 nm operation, a material with a gap of 0.6 to 0.75 meV is advantageous. A review of recent publications indicated that hexagonal boron Arsenide (h-BAs) band structure obtained with density functional theory (DFT) and hybrid functional correction has a band gap of 0.75 eV and further calculations predicted an absorption coefficient of ˜4×10⁴ cm⁻¹ at 1550 nm. Additionally, h-BAs has been predicted to have high electron mobilities in the range of 4 to 6×10⁴ cm²/V·s, making it perfectly suitable for high-speed sensing (low jitter, high count rate) applications. The previous calculation of bilayer h-BAs predicted a band gap of 0.65 eV in the most stable state, but the absorption coefficients were not available.

DFT calculations of bilayer h-BAs implemented through the Vienna Ab initio Simulation Package (VASP) were carried out. Perdew-Burke-Ernzerhof (PBE) parametrization of the generalized gradient approximation (GGA) is used with DFT-D3 to include Van der Waals forces. Atomic coordinates and lattice constants were relaxed until the intra-atomic forces are under 0.01 eV/Å. Two likely layer stackings are considered in which A atom of the top layer lies on B atom of bottom layer. When the top layer is not rotated, it is called AB stack and when rotated by 60°, it is called AB′ stack. Then, the energy-dependent absorption coefficients and the complex refractive indices were calculated. The results for bilayer h-BAs are shown in Table 1. Note that AB stack is only slightly higher energy than AB′ which bodes well for its growth as even higher alternate structures in h-BN and MoS₂ have been successfully grown. More importantly, this stack has a band gap of 0.60 eV and a large absorption coefficient a and extinction coefficient k at 1550 nm. The calculated complex refractive index for further optical modeling was used.

Silicon was chosen as the dielectric material for designing the photonic crystal substrate due to its transparency and high refractive index at 1550 nm. The photonic crystal substrate is realized by etching periodic air holes (period p, radius r) as a square lattice in the Si substrate (thickness t). The geometrical parameters (p, r, t) are optimized to achieve a broad absorption peak centered at 1550 nm with the peak absorption approaching 100%. To protect a BAs layer 30 from possible environmental interaction, a BAs layer was placed between hexagonal boron nitride (h-BN) layers 34, 36 as shown in FIG. 2. In FIG. 2 the h-BN layers and the BAs layer are shown side-by-side but the layers are shown “shingled.” In actuality, the h-BN layers and the BAs layer are coextensive and the BAs layer covers the lower h-BN layer and the upper h-BN layer covers the BAs layer. The nomenclature 1L indicates one layer and the nomenclature 5-15 L indicates five to fifteen layers. However, all results reported here were found not to change with variation in the number of h-BN layers. The optimized structure (FIG. 2) and its absorption spectra (FIG. 3) are shown. FIG. 3A plots the absorbance for a normally incident plane wave as a function of free-space wavelength for different numbers of h-BN buffer layers. The peak absorbance is close to 1 at 1.55 um and the FWHM (full width at half maximum) linewidth is 40 nm. The broad absorption linewidth makes the device suitable for applications involving either CW (continuous wave) or pulsed photon sources. The structure is also quite robust to the variations in the thickness of the buffer layer as can be seen from the different absorption spectra in FIG. 3A. FIG. 3B plots the absorption spectra for different incident angles. The absorption characteristic around 1.55 um remains practically invariant even at oblique incident angles. This broad angular absorption characteristics makes the device better amenable for realizing high resolution SPD array cameras with small pixel size.

### Current-Voltage (I-V) Calculations:

After having obtained the absorption profile, the I-V characteristics of the device were calculated with and without illumination. For device simulations, the 4 μm×4 μm PIN BAs bilayer on the PCS substrate with Ohmic contacts (no Schottky barriers) on the n and p sides—device architecture was considered and is shown in FIG. 4A. The calculated absorption rate profile inside the BAs layer for a normally incident plane wave of intensity 0.1 mW/cm² at 1550 nm is shown in FIG. 4B. The dotted circle denotes the boundary of the cylindrical air hole. The radiative generation/recombination of carriers, which is non-uniform due to the underlying photonic crystal substrate, is computed based on the absorption profile in FIG. 4B. In addition, nonradiative carrier generation/recombination via the Shockley-Read-Hall (SRH) mechanism was considered. The steady-state current-voltage (I-V) characteristics is calculated by solving drift-diffusion equations, Poisson equation and carrier continuity equations with spatially varying carrier generation-recombination, both in the absence of external illumination (dark current shown by black line in FIG. 4c) and in the presence of 0.1 mW/cm² illumination (colored line in FIG. 4c). Because of the extremely high carrier mobility expected in the BAs device, the diffusion length is much longer than the device channel length, the commonly used simple “Ohmic” boundary condition with the minority carrier density at contact being its equilibrium value is no longer valid and the proper boundary conditions should be that the gradient of minority carrier density at the contact vanishes,

$${( \frac{{dp}_{n}}{dx} )}_{c} = {( \frac{{dn}_{p}}{dx} )}_{c} = 0 ,$$

where pₙ (nₚ) is the hole (electron) density in the n (p) region.

Notice that the dark current in FIG. 4C, under reverse bias, is extremely small (˜fA) as expected and the photo current, even with extremely low illumination, is still pronounced. The signal to noise ratio (SNR), defined as the ratio of photo current to the dark current, is plotted in FIG. 4D. Notice that the SNR is very high at low bias, owing to small dark current and reaches a saturated value of ˜4 at large bias. Although it is tempting to operate at low bias for a larger SNR, the intrinsic region may not be fully depleted, and the transient characteristics of the device would be very slow due to large transit time at small bias. However, 100 mV in reverse bias is large enough to fully deplete the intrinsic BAs and the SNR at that bias is ˜5. Assuming a SNR of 2 is sufficient for sensing, this device can sense a steady state intensity of 40 nW/cm².

Since the device's area is 16 mm², in a steady state, it can sense ˜53,000 photons of 1550 nm wavelength per second. This level of ultra sensitivity is possible because the design manages to achieve near 100% absorption with one ML of absorber. Furthermore, the proposed detector structure is amenable for fabrication of a large array with small pixel pitch and high fill-factor, making it desirable for the single-photon imaging applications at 1550 nm. The underlying design principle is also suited for realizing low-photon flux cameras at mid and long wavelength IR spectrum through suitable material choices.

The ability to use the device for single photon detection depends on several other external factors such as RC time constant, integration time, high frequency circuitry, and measurable low current. A back-of-the-envelope estimate can be made of various times and limitations to identify the range of the operation for single photon detection.

First, the RC time constant is calculated. The capacitance, C, of the device, assuming an ML thickness of 1 nm, relative dielectric constant of 5 (of BAs), cross section area of 4 μm×1 nm, and dielectric thickness of 4 μm, we get a value of 4.5×10⁻²⁰ F. The calculated resistance R at zero bias (FIG. 4c) is 8×10¹² W and hence RC time constant has a value of 35×10⁻⁸ s or 0.35 μs.

It is instructive to calculate the transit time as well. Longer of these two times determines the rate of photon counting. The transit time is given by the ratio of length (4 μm) divided by the drift velocity which is the product of mobility (40,000 cm²/V·s) and electric field (=0.1V/4 μm). Substituting the values, we get 40 ps. With a larger bias, the transit time can be reduced to ˜ps, leading to jitter time of similar order of magnitude. However, ˜ps transit time is far smaller than the RC time. Hence RC time is used to calculate the current produced by the absorption of single photon. Since one e-h pair is created and is collected in RC time, the equivalent current is 0.5 pA. In other words, absorption of single photon gives a photo current of 0.5 pA whereas the dark current (FIG. 4c) is in fA. Equivalently, the SNR is ˜200. However, the photon has to arrive at a rate slower than 1 per microsecond to be detected as a single photon. For faster rates, all photons impinging within a microsecond will be collectively detected. Also, external circuit has to be able to handle MHz speeds. The other concern is the ability to measure low current and the effect of the associated noise. Normally, avalanche is exploited to amplify the current. Note that the design with 4 μm of carrier travel distance will naturally include avalanching at higher bias. However, the effect of avalanching is not considered in the calculation owing to the paucity of impact ionization coefficients in 2D materials.

In summary, a realistic design is provided for detecting low-photon flux and possibly to a single-photon level at room temperature. The designed structure is comprised of a 2D semiconductor, chosen with appropriate band gap to absorb the photons of desired wavelength, on a photonic crystal substrate, made of insulator transparent to the desired wavelength, for simultaneously achieving low dark current and high PDE. The design overcomes the inherent limiting tradeoff between photo detection efficiency and SNR in the state-of-the-art SPADs and can be readily extended to 2D materials that absorb light at other desired wavelengths. For a chosen wavelength of 1550 nm, appropriate absorbers include, but not limited to, BAs, BP, InSe, Zn₃P₂, NiP₂ or thin layer of 3D materials such as InGaAs, AlInAsSb or AlGaAsSb digital and random alloys with a band gap of 2 μm, and the insulator can be Si, or most III-V semiconductors. The proposed device can be both ultrasensitive and highly efficient at room temperature, particularly with the ability to achieve avalanching. The results presented here clearly establish the numerous advantages over the existing SPDs.

From the foregoing, it will be observed that numerous variations and modifications may be effectuated without departing from the spirit and scope of the invention. It is to be understood that no limitation with respect to the specific apparatus illustrated herein is intended or should be inferred.

The invention claimed is:

1. A low-photon detector comprising:
a 2D semiconductor on a photonic crystal substrate for simultaneously achieving low dark current and high PDE.

2. A device for enabling single photon detection at room temperature comprising a monolayer (ML) of 2D materials with photonic crystal substrate (PCS) using band-to-band absorption and low dark current to detect single photons at room temperature.

3. A device for enabling single photon detection at room temperature comprising a monolayer (ML) of hexagonal boron Arsenide with photonic crystal substrate (PCS) using band-to-band absorption and low dark current to detect single photons at room temperature, the hexagonal boron nitride sandwiched between hexagonal boron nitride.

4. A low-photon detector comprising:
a dielectric substate;
a first hexagonal Boron nitride (h-BN) layer covering the dielectric substate;
an absorber layer covering the first h-BN layer;
a second h-BN layer covering the absorber layer.

5. A detector according to claim 4 wherein the absorber layer comprises a monolayer of 2D semiconductor material chosen with a band gap to absorb photons of desired wavelength.

6. A detector according to claim 5 wherein the absorber layer is composed of a material selected from: BAs, BP, InSe, Zn₃P₂, or NiP₂.

7. A detector according to claim 4, wherein the absorber layer is composed of a material selected from InGaAs, AlInAsSb or AlGaAsSb.

8. A detector according to claim 4, wherein the substate is composed of a photonic crystal substate made of insulator transparent to a desired wavelength.

9. A low-photon detector comprising:
a dielectric substate;
a first hexagonal Boron nitride (h-BN) layer covering the dielectric substate;
a 2D monolayer absorber layer covering the first h-BN layer;
a second h-BN layer covering the absorber layer.

10. A detector according to claim 9 wherein the absorber layer comprises a material chosen with a band gap to absorb photons of desired wavelength.

11. A detector according to claim 10 wherein the absorber layer is composed of a material selected from: BAs, BP, InSe, Zn₃P₂, or NiP₂.

12. A detector according to claim 9, wherein the substate is composed of a photonic crystal substate made of insulator transparent to a desired wavelength.
